(19) United States
(12) Patent Application Publication
(10) Pub. No.: US 2012/0132986 A1
(43) Pub. Date: May 31, 2012

(54) SEMICONDUCTOR DEVICES AND METHODS OF MANUFACTURING THE SAME

(76) Inventors: Pil-Kyu Kang, Anyang-si (KR); Dae-Lok Bae, Seoul (KR); Gil-Heyun Choi, Seoul (KR); Suk-Chul Bang, Yongin-si (KR); Byung-Lyul Park, Seoul (KR); Kwang-Jin Moon, Suwon-si (KR); Dong-Chan Lim, Suwon-si (KR); Deok-Young Jung, Seoul (KR)

(21) Appl. No.: 13/251,676

(22) Filed: Oct. 3, 2011

(30) Foreign Application Priority Data
Nov. 26, 2010 (KR) 10-2010-0118456

(51) Int. Cl. H01L 29/78; H01L 27/092; H01L 21/8238

(52) U.S. Cl. 257/329; 438/212; 257/369; 257/E29.262; 257/E21.632; 257/E27.062

(57) ABSTRACT

A semiconductor device includes a substrate having a plurality of horizontal channel transistors formed thereon, an insulation layer structure on the substrate and covering the horizontal transistors, and a plurality of vertical channel transistors on the insulation layer structure.

### CROSS-REFERENCE TO RELATED APPLICATIONS

This application claims priority under 35 USC §119 to Korean Patent Application No. 10-2010-0118456 filed on Nov. 26, 2010, the disclosure of which is hereby incorporated by reference in it's entirety.

### BACKGROUND

1. Technical Field

Example embodiments relate to semiconductor devices and methods of manufacturing the same. More particularly, example embodiments relate to semiconductor devices having both of a vertical channel transistor and a horizontal channel transistor and methods of manufacturing the same

2. Description of the Related Art

Recently, semiconductor devices having both a vertical channel transistor and a horizontal channel transistor have been developed to increase the integration degree. The semiconductor devices may be formed on, for example, a silicon-on-insulator (SOI) substrate that has been formed by a wafer bonding process. That is, the vertical channel transistor may be formed on a cell region of the SOI substrate having a bulk substrate and a single crystalline silicon substrate attached to each other via an insulation layer, and the horizontal channel transistor may be formed on a peripheral region of the SOI substrate. However, the single crystalline substrate may not have a thickness sufficient enough for forming a well region under the horizontal channel transistor, and thus the horizontal channel transistor may not have good electrical characteristics.

### SUMMARY

Example embodiments provide a semiconductor device including a vertical channel transistor and a horizontal channel transistor and having good characteristics.

Example embodiments provide a method of manufacturing a semiconductor device including a vertical channel transistor and a horizontal channel transistor and having good characteristics.

According to example embodiments, there is provided a semiconductor device. The semiconductor device includes a substrate having a plurality of horizontal channel transistors formed thereon, an insulation layer structure formed on the substrate and covering the horizontal transistors, and a plurality of vertical channel transistors on the insulation layer structure.

In example embodiments, the substrate may include a cell region and a peripheral circuit region, and the horizontal channel transistors may be formed in the peripheral circuit region, and the vertical channel transistors may be formed on the insulation layer structure in the cell region.

In example embodiments, the substrate may include first, second and third well regions under the horizontal channel transistors.

In example embodiments, the horizontal channel transistors may include an NMOS transistor and a PMOS transistor. The second and third well regions may be formed under the NMOS and PMOS transistors, respectively, and the first well region may be formed under the second and third well regions. The first and third well regions may be n-type wells doped with n-type impurities, and the second well region may be a p-type well doped with p-type impurities.

In example embodiments, each vertical channel transistor may include an active pattern on the insulation layer structure, the active pattern including first and second impurity regions at lower and upper portions thereof, respectively, a gate insulation layer pattern surrounding a sidewall of the active pattern, and a gate electrode on the gate insulation layer pattern.

In example embodiments, the lower portion of the active pattern may extend in a first direction substantially parallel to a top surface of the substrate, and a plurality of the upper portions of the active pattern may have an island shape.

In example embodiments, the gate electrode may extend in a second direction substantially perpendicular to the first direction and substantially parallel to the top surface of the substrate, and may surround the gate insulation layer pattern.

In example embodiments, the semiconductor device may further include a bit line electrically connected to the first impurity region between the insulation layer structure and the vertical channel transistors.

In example embodiments, each of the lower portion of the active pattern and the bit line may extend in a first direction substantially parallel to a top surface of the substrate.

In example embodiments, the insulation layer structure may include first and second insulation layers sequentially stacked on the substrate.

According to example embodiments, there is provided a method of manufacturing a semiconductor device. In the method, a plurality of horizontal channel transistors are formed on a first substrate. A first insulation layer is formed on the first substrate to cover the horizontal channel transistors. A second substrate is attached on the first insulation layer. A plurality of vertical channel transistors is formed on the second substrate.

In example embodiments, prior to forming the horizontal channel transistors, a plurality of well regions may be further formed in the first substrate.

In example embodiments, when the well regions are formed, n-type impurities may be doped in the first substrate to form a first well region, and p-type impurities and n-type impurities may be doped on the first well region in the first substrate to form second and third well regions, respectively. When the horizontal channel transistors are formed, NMOS and PMOS transistors may be formed on the second and third well regions, respectively.

In example embodiments, prior to attaching the second substrate on the first insulation layer, a conductive layer may be further formed on the second substrate.

In example embodiments, a second insulation layer may be further formed on the conductive layer. When the second substrate is attached on the first insulation layer, the second insulation layer may be attached on the first insulation layer.
According to example embodiments, a semiconductor device is provided. The semiconductor device includes a substrate on which a plurality of first transistors and a plurality of second transistors are formed thereon, and each of the first transistors are formed in a peripheral circuit region of the substrate and include a first impurity region, and each of the second transistors are formed in the peripheral circuit region and include a second impurity region. Each of the first transistors has a horizontal channel disposed between the first impurity regions in a direction substantially parallel to a top surface of the substrate and each of the second transistors has a horizontal channel disposed between the second impurity regions in a direction substantially parallel to the top surface of the substrate. The semiconductor device further includes a first well region, a second well region and a third well region, with the second and third well regions formed under the first and second transistors, respectively and the first well region formed beneath the second and third well regions, an insulation layer structure formed on the substrate, the insulation layer structure covering the first and second transistors, a plurality of third transistors formed on the insulation layer structure in the cell region, with the third transistors each including an active pattern having a third impurity region and a fourth impurity region. An upper portion of the active pattern protrudes from a lower portion of the active pattern in a direction substantially perpendicular to the top surface of the substrate, and each of the third transistors includes a channel between the third and fourth impurity regions, respectively. The semiconductor device further includes a buried wiring formed between the insulation layer structure and the third transistors, a first insulating interlayer formed on the insulation layer structure to cover the lower portion of the active pattern, the buried wiring and the insulation layer structure in the cell region, a second insulating interlayer formed on the first insulating interlayer to cover the third transistors, a first plug formed in the second insulating layer in the cell region and electrically connected to the fourth impurity region and a second plug formed in the insulation layer structure and the first insulating interlayer in the peripheral circuit region and electrically connected to the first and second impurity regions.

According to example embodiments, the horizontal channel transistor may be formed on the first substrate, and the vertical channel transistor may be formed on the second substrate. Thus, there may be a sufficient space for forming the first, second and third well regions under the horizontal channel transistor in the first substrate so that the interference between the well regions may be reduced. Additionally, only the vertical channel transistor may be formed on the second substrate so that the second substrate may have a proper thickness for forming the vertical channel transistor by a cutting process.

### BRIEF DESCRIPTION OF THE DRAWINGS

Example embodiments of the present inventive concept can be understood in more detail from the following detailed description taken in conjunction with the accompanying drawings.

FIG. 1 is a cross-sectional view illustrating a semiconductor device in accordance with an example embodiment of the present inventive concept;

FIGS. 2 to 15 are cross-sectional views illustrating a method of manufacturing a semiconductor device in accordance with an example embodiment of the present inventive concept; and

FIG. 16 is a cross-sectional view illustrating a semiconductor device in accordance with an example embodiment of the present inventive concept.

### DETAILED DESCRIPTION OF THE EMBODIMENTS

Example embodiments of the present inventive concept will be described more fully hereinafter with reference to the accompanying drawings, in which example embodiments are shown. Example embodiments of the present inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. As used herein, the term “and/or” includes any and all combinations of one or more of the associated listed items.

Hereinafter, example embodiments will be explained in detail with reference to the accompanying drawings.

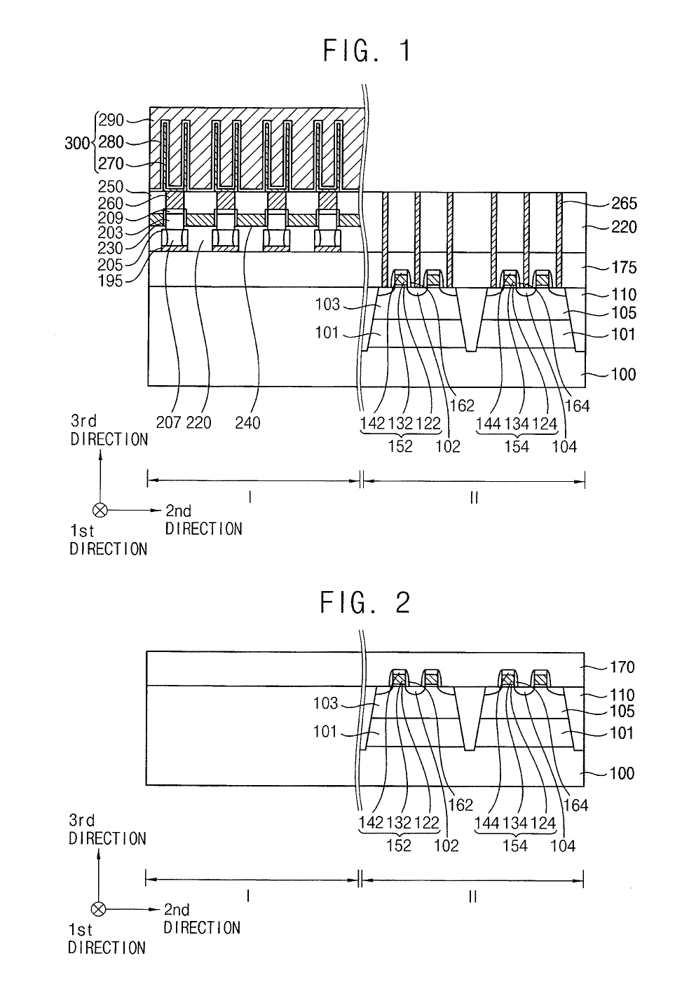

FIG. 1 is a cross-sectional view illustrating a semiconductor device in accordance with an example embodiment of the present inventive concept.

Referring to FIG. 1, the semiconductor device may include, for example, a substrate 100 on which first and second transistors are formed, an insulation layer structure 175 covering the first and second transistors on the substrate 100, and third transistors on the insulation layer structure 175. The semiconductor device may further include, for example, a buried wiring 195 between the insulation layer structure 175 and the third transistors, and a capacitor 300 electrically connected to the third transistors.

For example, the substrate 100 may include a semiconductor material such as silicon, germanium, silicon-germanium, etc., and may be divided into a first region I and a second region II. In an example embodiment, for example, the first region I may be a cell region in which memory cells are formed, and the second region II may be a peripheral circuit region in which peripheral circuits may be formed.

The first transistor may be formed, for example, in a negative-channel metal oxide semiconductor (NMOS) region of the second region II. The first transistor may include, for example, a first gate structure 152 and a first impurity region 102 at an upper portion of the substrate 100 adjacent to the first gate structure 152.

The first gate structure 152 may include, for example, a first gate insulation layer pattern 122, a first gate electrode 132 and a first gate mask 142 sequentially stacked on the substrate 100. In example embodiments, the first gate structure 152 may, for example, extend in a first direction substantially parallel to a top surface of the substrate 100. In example embodiments, a plurality of first gate structures 152 may be formed, for example, in a second direction substantially perpendicular to the first direction.

The first gate insulation layer pattern 122 may include, for example, silicon oxide or a metal oxide. The first gate electrode 132 may include, for example, a metal, a metal nitride and/or doped polysilicon. The first gate mask 142 may include, for example, silicon nitride.

In example embodiments, the first impurity region 102 may include, for example, n-type impurities, e.g., phosphorous, arsenic, etc.

The second transistor may be formed, for example, in a positive-channel metal oxide semiconductor (PMOS) region of the second region II. The second transistor may include, for example, a second gate structure 154 and a second impurity region 104 at an upper portion of the substrate 100 adjacent to the second gate structure 154.

The second gate structure 154 may include, for example, a second gate insulation layer pattern 124, a second gate electrode 134 and a second gate mask 144 sequentially stacked on the substrate 100. In example embodiments, the second gate structure 154 may extend, for example, in the first direction. In example embodiments, a plurality of second gate structures 154 may be formed, for example, in the second direction.

The second gate insulation layer pattern 124 may include, for example, silicon oxide or a metal oxide. The second gate electrode 134 may include, for example, a metal, a metal nitride and/or doped polysilicon. The second gate mask 144 may include, for example, silicon nitride.

In example embodiments, the second impurity region 104 may include, for example, p-type impurities, e.g., boron, gallium, etc.

The first transistor may have a channel between the first impurity regions 102, and the second transistor may have a channel between the second impurity regions 104. Thus, each of the first and second transistors may have a horizontal channel extending in a direction substantially parallel to the top surface of the substrate 100. Accordingly, each of the first and second transistors may be referred to as a horizontal channel transistor, and a plurality of horizontal channel transistors may be formed on the substrate 100.

The NMOS region and the PMOS region may be divided by an isolation layer 110 at an upper portion of the substrate 100. The isolation layer 110 may include, for example, silicon oxide.

A plurality of well regions 101, 103 and 105 may be formed under the horizontal channel transistors in the substrate 100.

For example, second and third well regions 103 and 105 may be formed under the first and second transistors, respectively, and a first well region 101 may be formed beneath the second and third well regions 103 and 105.

In example embodiments, the first and third well regions 101 and 105 may include, for example, n-type impurities, e.g., phosphorous, arsenic, etc., and the second well region 103 may include, for example, p-type impurities, e.g., boron, gallium, etc. That is, the first and third well regions 101 and 105 may be an n-type well region, and the second well region 103 may be a p-type well region.

In example embodiments, the insulation layer structure 175 may include oxide, e.g., silicon oxide.

Each third transistor may include, for example, an active pattern, a third gate insulation layer pattern 230, and a third gate electrode 240. The active pattern may have, for example, lower and upper portions 207 and 203 including third and fourth impurity regions 205 and 209, respectively. The third gate insulation layer pattern 230 may cover a sidewall of the active pattern. The third gate electrode 240 may be formed on the third gate insulation layer 230.

The active pattern may include, for example, a semiconductor material such as silicon, germanium, silicon-germanium, etc. In example embodiments, the active pattern may include, for example, single crystalline silicon.

For example, in example embodiments, the lower portion 207 of the active pattern may extend in the first direction, and a plurality of upper portions 203 of the active pattern each of which may have a pillar shape, e.g., a cylindrical shape, a square pillar, etc. may be formed. That is, the upper portions 203 of the active pattern may protrude from, for example, the lower portion 207 of the active pattern in a third direction substantially perpendicular to the top surface of the substrate 100, and may have a width, for example, smaller than that of the lower portion 207.

The third impurity region 205 may be formed at a sidewall of the lower portion 207 of the active pattern. In example embodiments, the third impurity region 205 may make contact with the buried wiring 195 therebeneath. Alternatively, the third impurity region 205 may not make contact with the buried wiring 195 thereunder. In this case, a contact (not shown) may be further formed, and thus the third impurity region 205 and the buried wiring 195 may be electrically connected to each other via the contact. The third impurity region 205 may include n-type or p-type impurities. The fourth impurity region 209 may be formed at an upper portion of the upper portion 203 of the active pattern. The fourth impurity region 209 may include n-type or p-type impurities.

Each third transistor may have a channel between the third and fourth impurity regions 205 and 209. Thus, each third transistor may be referred to as a vertical channel transistor.

The third gate insulation layer pattern 230 may be formed at a sidewall of the upper portion 203 of the active pattern. The third gate insulation layer pattern 230 may include, for example, silicon oxide or a metal oxide, e.g., aluminum oxide, hafnium oxide, zirconium oxide, etc.

In example embodiments, the third gate electrode 240 may extend, for example, in the second direction, and cover the third gate insulation layer pattern 230. In example embodiments, a plurality of third gate electrodes 240 may be formed, for example, in the first direction. The third gate electrode 240 may include, for example, doped polysilicon, a metal and/or a metal compound. For example, the third gate electrode 240 may include tungsten, titanium, tantalum, aluminum, aluminum nitride, tungsten nitride, titanium nitride, titanium aluminum nitride, tantalum nitride, etc.

In example embodiments, the buried wiring 195 may extend, for example, in the first direction on the insulation layer structure 175, and may make contact with the lower portion 207 of the active pattern. The buried wiring 195 may include, for example, doped polysilicon, a metal and/or a metal compound. For example, the buried wiring 195 may include tungsten, titanium, tantalum, molybdenum, iridium, hafnium, zirconium, ruthenium, platinum, nickel, aluminum, copper, tungsten nitride, aluminum nitride, tantalum nitride, titanium nitride, titanium aluminum nitride, molybdenum nitride, hafnium nitride, zirconium nitride, doped polysilicon, etc.

The capacitor 300 may be electrically connected to the fourth impurity region 209 in the active pattern via a first plug 260. The capacitor 300 may include, for example, a lower electrode 270 on the first plug 260, and a dielectric layer pattern 280 and an upper electrode 290 sequentially stacked on the lower electrode 270. The lower and upper electrodes 270 and 290 may include, for example, doped polysilicon, a metal, a metal nitride and/or a metal silicide. For example, the dielectric layer pattern 280 may include silicon nitride or a high-k dielectric material having a dielectric constant higher than that of silicon nitride, e.g., tantalum oxide, hafnium oxide, aluminum oxide, zirconium oxide, etc.

A first insulating interlayer 220 may be formed on the insulation layer structure 175 to cover the lower portion 207 of the active pattern and the buried wiring 195 in the first region I. The first insulating interlayer 220 may have, for example, a height higher in the second region II than in the first region I.

A second insulating interlayer 250 may be formed on the first insulating interlayer 220 to cover the upper portion 203 of the active pattern, the third gate insulation layer pattern 230 and the third gate electrode 240.

The first and second insulating interlayers 220 and 250 may include, for example, an oxide, e.g., silicon oxide.

A second plug 265 may be further formed through the insulation layer structure 175 and the first insulating interlayer 220 in the second region II to be electrically connected to a variety of wirings (not shown).

In the semiconductor device, the horizontal channel transistors may be formed on the substrate 100, and the vertical channel transistors may be independently formed on the insulation layer structure 175 on the substrate 100. Thus, the well regions 101, 103 and 105 may be formed under the horizontal channel transistors in a sufficiently large space, and the vertical channel transistors may have a proper thickness regardless of the horizontal channel transistors.

FIGS. 2 to 15 are cross-sectional views illustrating a method of manufacturing a semiconductor device in accordance with example embodiments.

Referring to FIG. 2, a first substrate 100 is divided into a first region I and a second region II. A plurality of well regions 101, 103 and 105, an isolation layer 110 and horizontal channel transistors may be formed in or on the second region II of the first substrate 100, and a first insulation layer 170 covering the horizontal channel transistors may be formed on the first substrate 100.

For example, a first mask (not shown) covering the first region I of the first substrate 100 may be formed, and first impurities may be implanted into the first substrate 100 using the first mask as an ion implantation mask to form a first well region 101 at a portion of the first substrate 100 in the second region II. The first substrate 100 may include, for example, a semiconductor material, e.g., silicon, germanium, silicon-germanium, etc. In example embodiments, the first impurities may include, for example, n-type impurities, e.g., phosphorous, arsenic, etc., and thus the first well region 101 may be an n-type well region.

A second mask (not shown) partially covering the second region II of the first substrate 100 may be formed, and second impurities may be, for example, implanted into the first substrate 100 using the first and second masks as an ion implantation mask to form a third well region 105 at a portion of the first substrate 100 on the first well region 101. In example embodiments, the second impurities may include, for example, n-type impurities, e.g., phosphorous, arsenic, etc., and thus the third well region 105 may be an n-type well region.

After removing the first and second masks, a third mask (not shown) covering the first region I and a portion of the second region II of the first substrate 100 may be formed, and third impurities may be, for example, implanted into the first substrate 100 using the third mask as an ion implantation mask to form a second well region 103 at a portion of the first substrate 100 on the first well region 101. In example embodiments, the third impurities may include, for example, p-type impurities, e.g., boron, gallium, etc., and thus the second well region 103 may be a p-type well region.

After removing the third mask, a fourth mask (not shown) covering the first region I and a portion of the second region II of the first substrate 100 may be formed, and an upper portion of the first substrate 100 may be removed using the fourth mask as an etching mask to form a trench (not shown). In example embodiments, the trench may be formed between the second and third well regions 103 and 105 to have, for example, a depth deeper than that of the first well region 101. Thus, the first well region 101 may be divided into, for example, two parts, and the second and third well regions 103 and 105 may be spaced apart from each other by the trench. Alternatively, the trench may be formed to have, for example, a depth deeper than those of the second and third well regions 103 and 105 but shallower than that of the first well region 101. After removing the fourth mask, the isolation layer 110 may be formed to fill the trench. In example embodiments, the isolation layer 110 may be formed using, for example, silicon oxide.

A gate insulation layer, a gate electrode layer and a gate mask layer may be sequentially formed on the first substrate 100, and the gate mask layer may be patterned by, for example, a photolithography process to form first and second gate masks 142 and 144 partially covering the first substrate 100 in the second region II. The first and second gate masks 142 and 144 may be formed to partially overlap the second and third well regions 103 and 105, respectively. The gate electrode layer and the gate insulation layer may be patterned using the first and second gate masks 142 and 144 as an etching mask to form first and second gate electrodes 132 and 134, and first and second gate insulation layer patterns 122 and 124, respectively. Thus, a first gate structure 152 having a first gate insulation layer pattern 122, a first gate electrode 132 and a first gate mask 142 sequentially stacked on the first substrate 100, and a second gate structure 154 having a second gate insulation layer pattern 124, a second gate electrode 134 and a second gate mask 144 sequentially stacked on the first substrate 100 may be formed in the second region II. The first and second gate structures 152 and 154 may overlap the second and third well regions 103 and 105, respectively. In example embodiments, each of the first and second gate structures 152 and 154 may be formed to extend, for example, in a first direction substantially parallel to a top surface of the first substrate 100. In example embodiments, a plurality of first gate structures 152 may be formed, for example, in a second direction substantially perpendicular to the first direction, and a plurality of second gate structures 154 may be formed, for example, in the second direction.

A fifth mask (not shown) covering the first region I and the third well region 105 of the first substrate 100 may be formed, and fourth impurities may be, for example, implanted into the first substrate 100 using the fifth mask and the first gate structure 152 as an ion implantation mask to form a first impurity region 102 at an upper portion of the first substrate 100 adjacent to the first gate structure 152. In example embodiments, the fourth impurities may include, for example, n-type impurities, e.g., phosphorous, arsenic, etc., and thus the first impurity region 102 may be an n-type impurity region.

After removing the fifth mask, a sixth mask (not shown) covering the first region I and the second well region 103 of the first substrate 100 may be formed, and fifth impurities may be, for example, implanted into the first substrate 100 using the sixth mask and the second gate structure 154 as an ion implantation mask to form a second impurity region 104 at an upper portion of the first substrate 100 adjacent to the second gate structure 154. In example embodiments, the fifth impurities may include, for example, p-type impurities, e.g., boron, gallium, etc., and thus the second impurity region 104 may be a p-type impurity region.

The first gate structure 152 and the first impurity region 102 may form a first transistor, and the second gate structure 154 and the second impurity region 104 may form a second transistor. In example embodiments, the first and second transistors may be NMOS and PMOS transistors, respectively. Each of the first and second transistors may have a channel extending in a direction substantially parallel to the top surface of the first substrate 100, and thus may be referred to as a horizontal channel transistor.

After removing the sixth mask, a spacer layer may be formed on the first substrate 100 to cover the first and second gate structures 152 and 154. The spacer layer may be partially removed by, for example, an anisotropic etching process to form first and second gate spacers 162 and 164 on sidewalls of the first and second gate structures 152 and 154, respectively. In example embodiments, the spacer layer may be formed using, for example, silicon nitride.

A first insulation layer 170 may be formed on the first substrate 100 to cover the first and second transistors and the first and second gate spacers 162 and 164. In example embodiments, the first insulation layer 170 may be formed using, for example, silicon oxide.

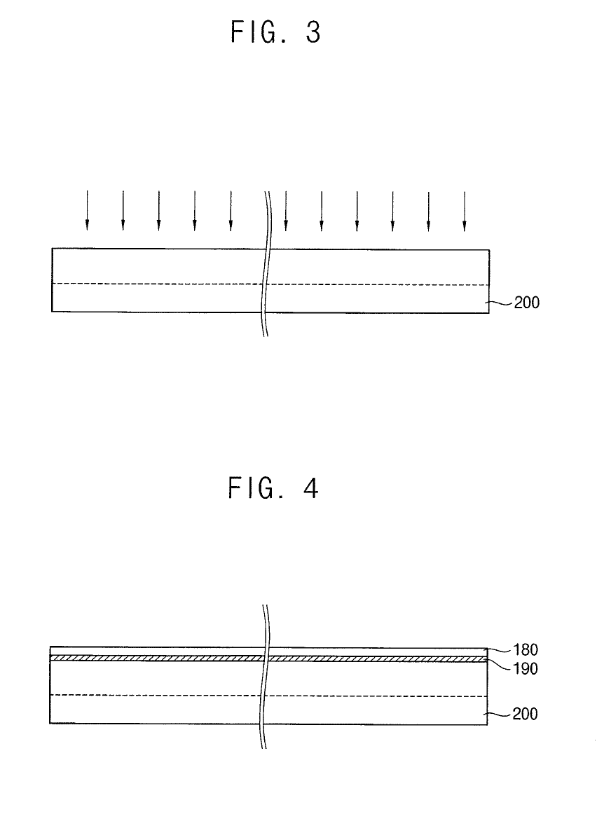

Referring to FIG. 3, sixth impurities may be implanted into a second substrate 200 by, for example, an ion implantation process.

The second substrate 200 may include, for example, a semiconductor material, e.g., silicon, germanium, silicon-germanium, etc. In example embodiments, the second substrate 200 may include single crystalline silicon.

In example embodiments, the sixth impurities may include, for example, hydrogen ions, and a lattice defect may be generated in the second substrate 200 due to the implanted hydrogen ions. The second substrate 200 may be divided into, for example, two parts in a subsequent process at a portion in which the lattice defect is generated, and one of them may be removed. The location into which the sixth impurities are implanted may be varied by controlling the ion implantation energy for accelerating the sixth impurities. In example embodiments, the sixth impurities may be, for example, implanted into a depth of about 1,000 to about 6,000 Å from a top surface of the second substrate 200.

Referring to FIG. 4, a first conductive layer 190 and a second insulation layer 180 may be sequentially formed on the second substrate 200.

The first conductive layer 190 may be formed on the second substrate 200 using, for example, a metal, a metal compound and/or doped polysilicon by a sputtering process, a chemical vapor deposition (CVD) process, an atomic layer deposition (ALD) process, a plasma enhanced chemical vapor deposition (PECVD) process, a pulse laser deposition (PLD) process, a vacuum deposition process, etc. For example, the first conductive layer 190 may be formed using tungsten, titanium, tantalum, molybdenum, iridium, hafnium, zirconium, ruthenium, platinum, nickel, aluminum, copper, tungsten nitride, aluminum nitride, tantalum nitride, titanium nitride, titanium aluminum nitride, molybdenum nitride, hafnium nitride, zirconium nitride, doped polysilicon, etc. These may be used alone or in a combination thereof.

Before forming the first conductive layer 190 on the second substrate 200, a barrier layer (not shown) may be further formed. The barrier layer may prevent the material of the first conductive layer 190 from diffusing into the second substrate 200. The barrier layer may be formed using, for example, a metal and/or a metal compound. For example, the barrier layer may be formed using titanium, titanium nitride, titanium silicide, tantalum, tantalum nitride, tantalum silicide, molybdenum, molybdenum nitride, hafnium, hafnium nitride, tungsten, tungsten nitride, tungsten silicide, zirconium, zirconium nitride, zirconium silicide, nickel, nickel silicide, aluminum, aluminum nitride, cobalt silicide, etc. These may be used alone or in a combination thereof.

The second insulation layer 180 may be formed by, for example, a radical oxidation process, a CVD process, a PECVD process, a spin coating process, a high density plasma chemical vapor deposition (HDP-CVD) process, a thermal oxidation process, etc. For example, the second insulation layer 180 may be formed using silicon oxide.

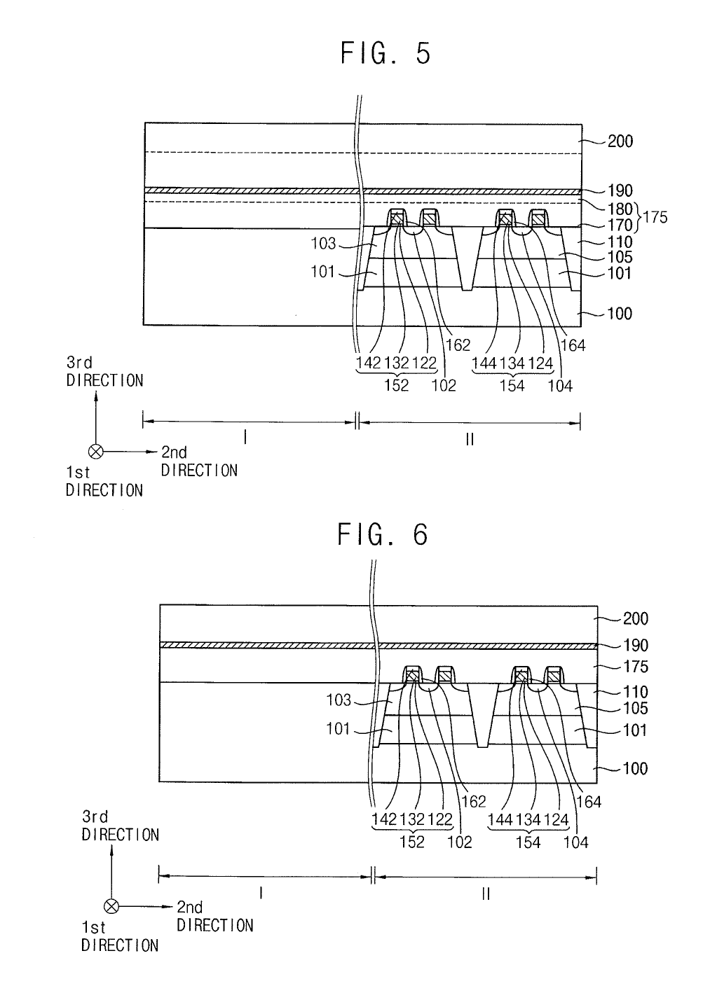

Referring to FIG. 5, the second substrate 200 may be arranged so that the second insulation layer 180 may face the first insulation layer 170 of the first substrate 100, and the first and second substrates 100 and 200 may be attached to each other.

In example embodiments, the first and second substrates 100 and 200 may be attached to each other by, for example, a heat press process. Thus, the first insulation layer 170 on the first substrate 100 and the second insulation layer 180 on the second substrate 200 may be attached to form an insulation layer structure 175. When the first and second insulation layers 170 and 180 include substantially the same material, e.g., silicon oxide, the first and second insulation layers 170 and 180 may be merged into a single layer structure. Hereinafter, only the single layer structure is described for the convenience of explanation.

Alternatively, for example, an adhesive layer (not shown) may be further formed between the first and second insulation layers 170 and 180, and the first and second substrate 100 and 200 may be attached by means of the adhesive layer. The adhesive layer may include, for example, heat resistant polymer.

Referring to FIG. 6, the second substrate 200 may be partially removed so that the thickness of the second substrate 200 may be controlled in consideration of a vertical channel transistor subsequently formed. In example embodiments, the second substrate 200 may be, for example, partially removed to have a thickness of about 1,000 to about 6,000 Å.

In example embodiments, the second substrate 200 may be thermally treated so that the second substrate 200 may be cut at the portion in which the lattice defect is generated due to the sixth impurities. Thus, a portion of the second substrate 200 having a surface on which the first conductive layer 190 is not formed may be removed.

Alternatively, the second substrate 200 may be partially removed by, for example, a laser cutting process, a grinding process, a chemical mechanical polishing (CMP) process, an etching process, etc.

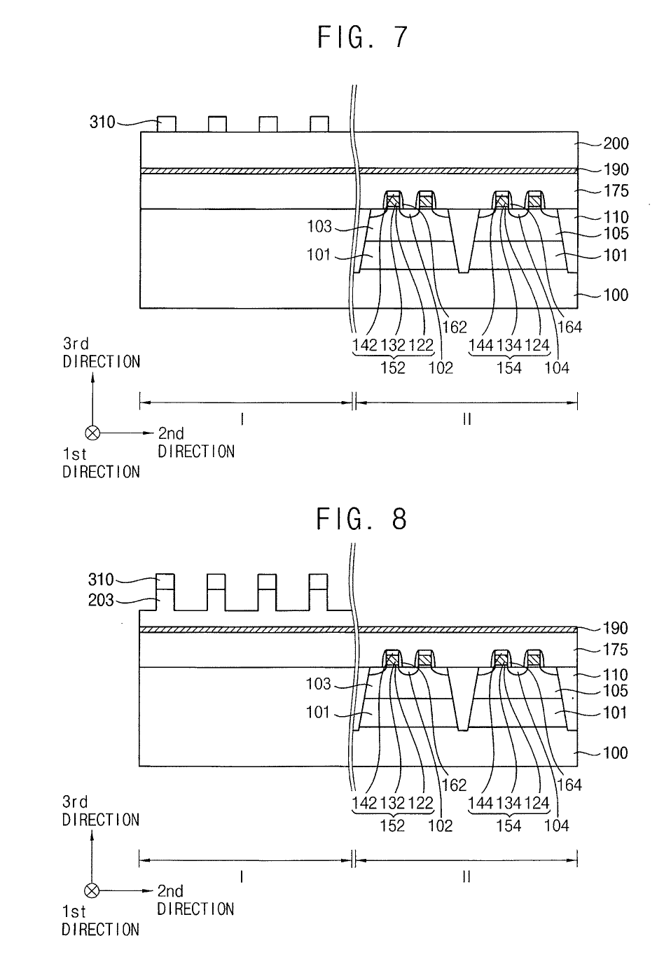

Referring to FIG. 7, a gate mask layer (not shown) may be formed on the second substrate 200, and the gate mask layer may be etched to form a third gate mask 310 in the first region I.

The third gate mask 310 may be formed using a material having an etching selectivity with respect to the second substrate 200. For example, the third gate mask 310 may be formed using silicon nitride or silicon oxynitride. The third gate mask 310 may be formed by, for example, a CVD process, a PECVD process, an HDP-CVD process, etc. In example embodiments, a plurality of third gate masks 310, each of which may have, for example, a pillar shape, e.g., a cylindrical shape or a square pillar shape, may be formed.

Referring to FIG. 8, the second substrate 200 may be partially removed using the third gate mask 310 as an etching mask to form an upper portion 203 of an active pattern at the second substrate 200 in the first region I.

The upper portion 203 of the active pattern may be formed by, for example, an anisotropic etching process. In example embodiments, the upper portion 203 of the active pattern may have, for example, a pillar shape according to the shape of the third gate mask 310, and may protrude in a third direction substantially perpendicular to the top surface of the first substrate 100. In example embodiments, a plurality of upper portions 203 of the active pattern may be formed.

The third gate mask 310 may not be formed on a portion of the second substrate 200 in the second region II, and thus the portion of the second substrate 200 in the second region II may be removed by, for example, the etching process to expose a portion of the first conductive layer 190 in the second region II.

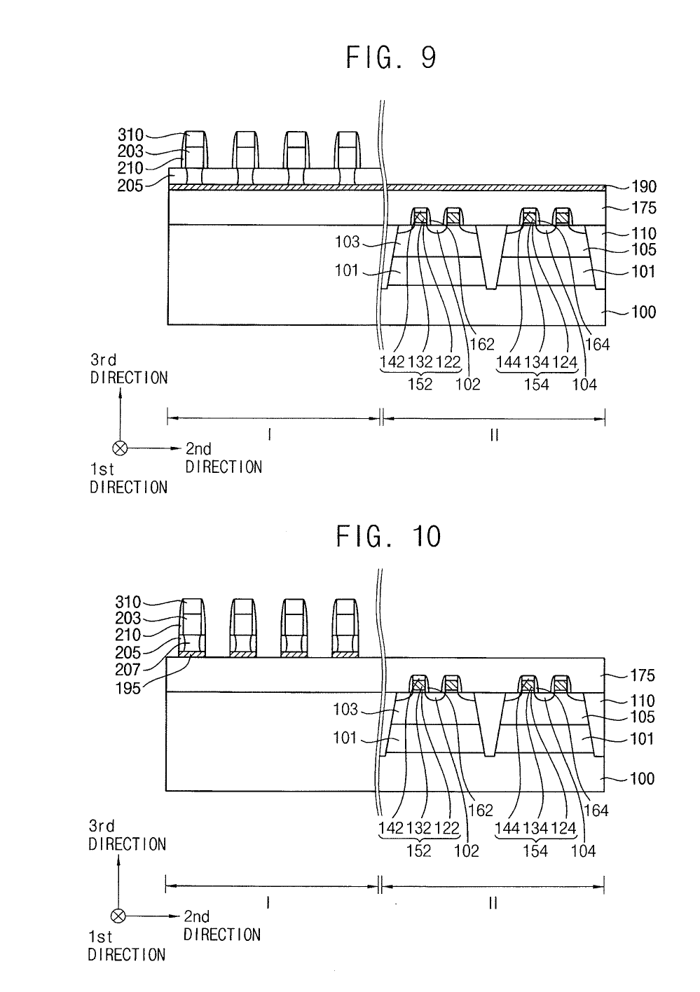

Referring to FIG. 9, a third gate spacer 210 may be formed on sidewalls of the third gate mask 310 and the upper portion 203 of the active pattern, and a third impurity region 205 may be formed at a lower portion of the second substrate 200.

The third gate spacer 210 may be formed using, for example, a nitride, e.g., silicon nitride, or an oxynitride, e.g., silicon oxynitride. In example embodiments, a gate spacer layer may be formed on the third gate mask 310, the upper portion 203 of the active pattern and the first conductive layer 190, and the gate spacer layer may be, for example, anisotropically etched to form the third gate spacer 210 on the sidewalls of the third gate mask 310 and the upper portion 203 of the active pattern. In example embodiments, a plurality of third gate spacers 210 may be formed.

The third impurity region 205 may be formed by, for example, doping seventh impurities into the lower portion of the second substrate 200 using the third gate mask 310 and the third gate spacer 210 as an ion implantation mask. Thus, the third impurity region 205 may be formed at a portion of the second substrate 200 that is not covered by the upper portion 203 of the active pattern and the third gate spacer 210. However, a portion of the seventh impurities may be diffused so that the third impurity region 205 may be also formed under the third gate spacer 210.

In example embodiments, the third impurity region 205 may be formed to make contact with and thus be electrically connected to the first conductive layer 190 beneath the second substrate 200 in the first region I. Alternatively, the third impurity region 205 may be formed not to make contact with the first conductive layer 190. In this case, a contact (not shown) may be formed in a subsequent process, so that the third impurity region 205 and the first conductive layer 190 may be electrically connected to each other via the contact. The seventh impurities may include p-type or n-type impurities.

Referring to FIG. 10, a seventh mask (not shown) may be formed on the third gate mask 310, the third gate spacer 210 and the lower portion of the second substrate 200, and the lower portion of the second substrate 200 and the first conductive layer 190 may be etched using the seventh mask and the third gate spacer 210 as an etching mask to form a lower portion 207 of the active pattern and a buried wiring 195, respectively.

In example embodiments, a plurality of lower portions 207 of the active pattern and a plurality of buried wirings 195 may be formed, for example, in the second direction, and each lower portion 207 of the active pattern and each buried wiring 195 may be formed to extend, for example, in the first direction. In example embodiments, the buried wiring 195 may serve as, for example, a bit line. By the etching process, the third impurity region 205 may remain under the third gate spacer 210 in the lower portion 207 of the active pattern. The upper portion 203 and the lower portion 207 may define the active pattern.

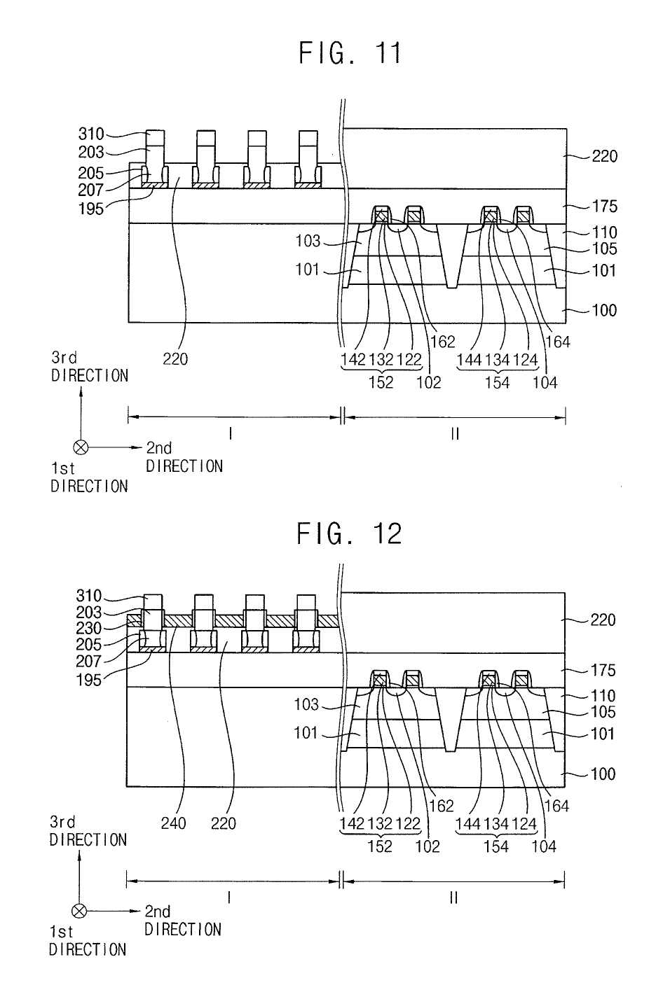

Referring to FIG. 11, the third gate spacer 210 may be removed from the third gate mask 310 and the upper portion 203 of the active pattern.

A first insulating interlayer 220 covering the third gate mask 310, the active pattern, the buried wiring 195 and the insulation layer structure 175 may be formed, and the first insulating interlayer 220 in the first region I may be partially removed. In example embodiments, the first insulating interlayer 220 may be formed to cover the lower portion 207 of the active pattern, and thus the third impurity region 205 may be also covered by the first insulating interlayer 220. That is, the first insulating interlayer 220 may have, for example, a height between the lower portion 207 of the active pattern and the upper portion 203 of the active pattern in the first region I.

Referring to FIG. 12, a third gate insulation layer pattern 230 may be formed on a sidewall of the upper portion 203 of the active pattern.

In example embodiments, the third gate insulation layer pattern 230 may be formed to surround the sidewall of the upper portion 203 of the active pattern that is not covered by the first insulating interlayer 220. The third gate insulation layer pattern 230 may be formed using, for example, silicon oxide or a metal oxide, e.g., aluminum oxide, hafnium oxide, zirconium oxide, etc. The third gate insulation layer pattern 230 may be formed by, for example, a thermal oxidation process, a CVD process, an ALD process, a sputtering process, etc.

A second conductive layer covering the third gate insulation layer pattern 230 may be formed on the first insulating interlayer 220, and the second conductive layer may be patterned to form a third gate electrode 240. The second conductive layer may be formed using, for example, doped polysilicon, a metal and/or a metal compound. For example, the second conductive layer may be formed using tungsten, titanium, tantalum, aluminum, aluminum nitride, tungsten nitride, titanium nitride, titanium aluminum nitride, tantalum nitride, etc. These may be used alone or in a combination thereof.

In example embodiments, a plurality of third gate electrodes 240 may be formed in, for example, the third direction, and each third gate electrode 240 may be formed to extend, for example, in the second direction.

In example embodiments, the third gate electrode 240 may be formed to have, for example, a height substantially lower than that of a top surface of the upper portion 203 of the active pattern. Thus, the upper portion 203 of the active pattern may not be completely covered by the third gate electrode 240, and thus may be exposed.

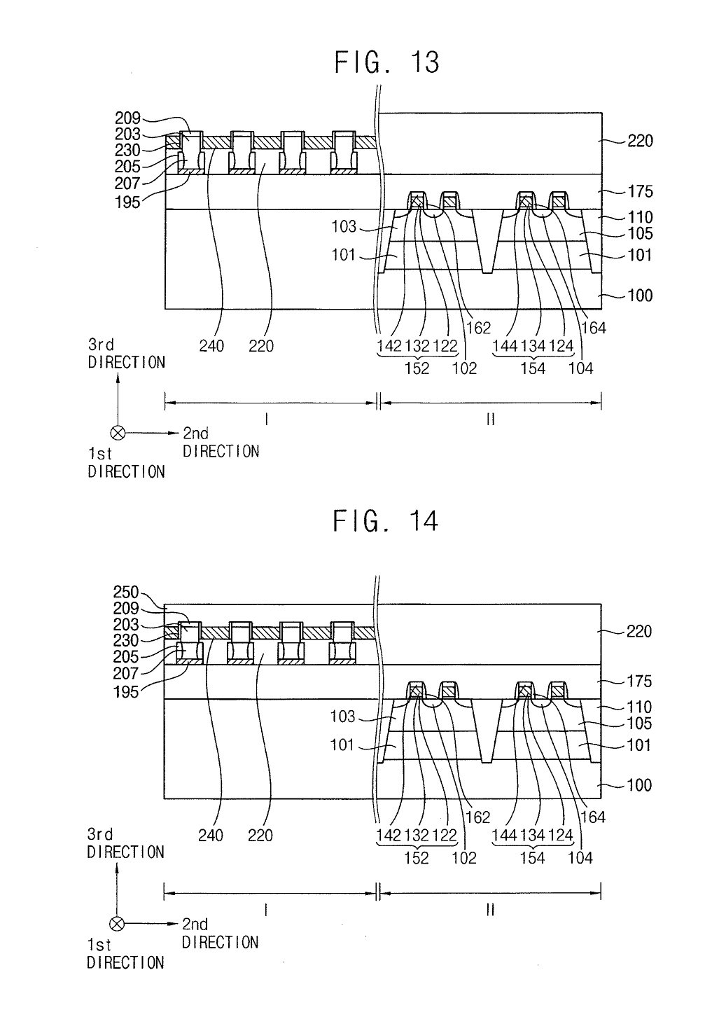

Referring to FIG. 13, the third gate mask 310 may be removed to expose a top surface of the upper portion 203 of the active pattern.

Eighth impurities may be, for example, implanted into the exposed upper portion 203 of the active pattern to form a fourth impurity region 209. The eighth impurities may include p-type or n-type impurities. The eighth impurities may be substantially the same as the seventh impurities.

Consequently, when the fourth impurity region 209 is formed, a third transistor having the active pattern including the third and fourth impurity regions 205 and 209, the third gate insulation layer pattern 230 and the third gate electrode 240 may thereby be formed in the first region I.

The third and fourth impurity regions 205 and 209 of the third transistor may be formed at the lower portion 207 and the upper portion 203 of the active pattern, respectively, and thus a channel therebetween may be formed in a third direction substantially perpendicular to the top surface of the first substrate 200. Thus, the third transistor may be a vertical channel transistor.

A plurality of active patterns may be formed, and a result a plurality of third transistors may also be formed.

Referring to FIG. 14, a second insulating interlayer 250 may be formed on the first insulating interlayer 220 to cover the third transistor and the third gate electrode 240.

In example embodiments, the second insulating interlayer 250 may be formed to have, for example, a height substantially the same as that of the first insulating interlayer 220 in the second region II. In example embodiments, the second insulating interlayer 250 may be formed using, for example, an oxide, e.g., silicon oxide.

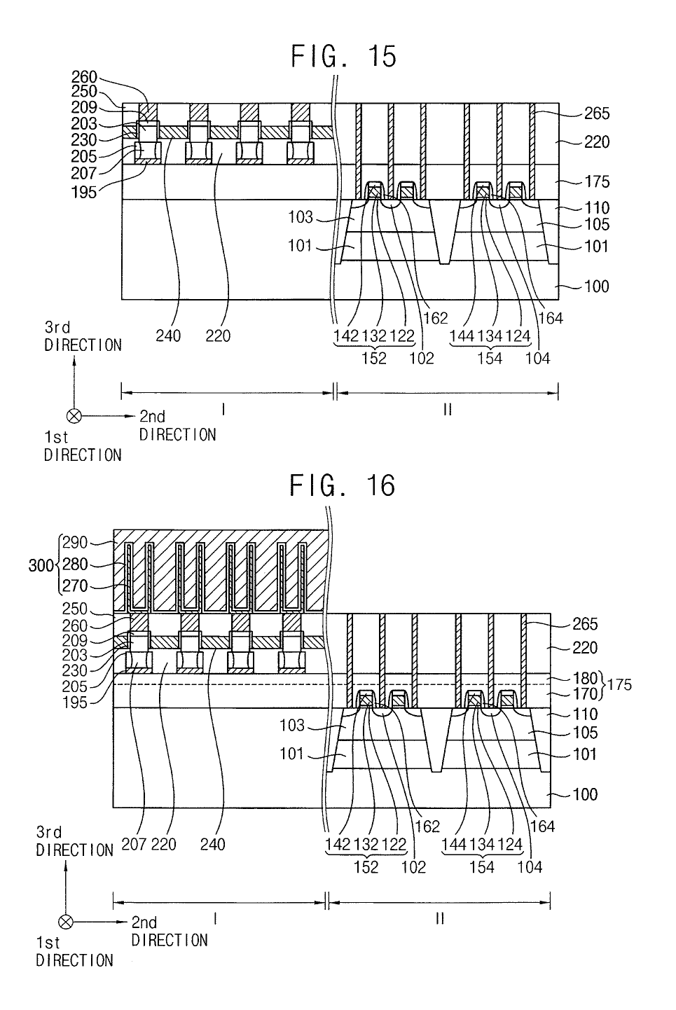

Referring to FIG. 15, the first and second insulating interlayers 220 and 250 may be partially removed to form first and second openings (not shown). The first opening may expose a top surface of the upper portion 203 of the active pattern, and the second opening may expose top surfaces of the first and second impurity regions 102 and 104.

A third conductive layer filling the first and second openings may be formed on the upper portion 203 of the active pattern, the first and second impurity regions 102 and 104, and the first and second insulating interlayers 220 and 250, and the third conductive layer may be planarized until top surfaces of the first and second insulating interlayers 220 and 250 are exposed to form first and second plugs 260 and 265. The first plug 260 may be electrically connected to the fourth impurity region 209, and the second plug 265 may be electrically connected to the first and second impurity regions 102 and 104.

Referring to FIG. 1 again, a capacitor 300 electrically connected to the first plug 260 may be formed to manufacture the semiconductor device.

For example, a mold layer (not shown) may be formed on the second insulating interlayer 250, and the mold layer may be partially removed to form a third opening (not shown) exposing the first plug 260. The mold layer may be formed using, for example, silicon oxide. A fourth conductive layer may be formed on the first plug 260, a sidewall of the third opening and the mold layer, and a sacrificial layer (not shown) filling a remaining portion of the third opening may be formed on the fourth conductive layer. The fourth conductive layer may be formed using, for example, doped polysilicon, a metal, a metal nitride and/or a metal silicide. The sacrificial layer and the fourth conductive layer may be planarized until a top surface of the mold layer is exposed to form a lower electrode 270 on the first plug 260 and the sidewall of the third opening. The sacrificial layer may be removed, and a dielectric layer pattern 280 may be formed on the lower electrode 270. An upper electrode 290 may be formed on the dielectric layer pattern 280 to form the capacitor 300. The dielectric layer pattern 280 may be formed using, for example, silicon nitride or a high-k dielectric material having a dielectric constant higher than that of silicon nitride, e.g., tantalum oxide, hafnium oxide, aluminum oxide, zirconium oxide, etc. The upper electrode 290 may be formed using, for example, doped polysilicon, a metal, a metal nitride and/or a metal silicide.

As illustrated above, with example embodiments of the present inventive concept, the horizontal channel transistor may be formed on and in the first substrate 100, and the vertical channel transistor may be formed on and in the second substrate 200. Thus, there may be a large space for forming the well regions 101, 103 and 105 under the horizontal transistor, and thus the interference between the well regions 101, 103 and 105 may be prevented. Additionally, only the vertical channel transistor may be formed on and in the second substrate 200, and thus the second transistor may have a proper thickness by cutting the second substrate 200.

FIG. 16 is a cross-sectional view illustrating a semiconductor device in accordance with an example embodiments.

The semiconductor device may be substantially the same as or similar to that of FIG. 1 except for an insulation layer structure. Thus, like reference numerals refer to like elements, and repetitive explanations thereon are omitted here.

An insulation layer structure 175 may include a first insulation layer 170 and a second insulation layer 180 sequentially stacked on the first substrate 100 in the second region II. The first and second insulation layers 170 and 180 may include different materials. For example, the first insulation layer 170 may include silicon oxide, and the second insulation layer 180 may include silicon nitride.

Having described example embodiments of the present inventive concept, it is further noted that it is readily apparent to those of reasonable skill in the art that various modifications may be made without departing from the spirit and scope of the invention which is defined by the metes and bounds of the appended claims.

What is claimed is:

1. A semiconductor device, comprising:
a substrate having a plurality of horizontal channel transistors formed thereon;
an insulation layer structure on the substrate, the insulation layer structure covering the horizontal transistors; and
a plurality of vertical channel transistors on the insulation layer structure.

2. The semiconductor device of claim 1, wherein the substrate includes a cell region and a peripheral circuit region,
and wherein the horizontal channel transistors are formed in the peripheral circuit region, and the vertical channel transistors are formed on the insulation layer structure in the cell region.

3. The semiconductor device of claim 2, wherein the substrate includes a first well region, a second well region and a third well region under the horizontal channel transistors.

4. The semiconductor device of claim 3,
wherein the horizontal channel transistors include an negative channel metal oxide semiconductor (NMOS) transistor and a positive channel metal oxide semiconductor (PMOS) transistor,
wherein the second and third well regions are formed under the NMOS and PMOS transistors, respectively, and the first well region is formed under the second and third well regions,
and wherein the first and third well regions are n-type wells doped with n-type impurities, and the second well region is a p-type well doped with p-type impurities.

5. The semiconductor device of claim 1, wherein each vertical channel transistor includes:
an active pattern on the insulation layer structure, the active pattern including a first impurity region and a second impurity region formed at a lower portion and an upper portion thereof, respectively;
a gate insulation layer pattern surrounding a sidewall of the active pattern; and
a gate electrode on the gate insulation layer pattern.

6. The semiconductor device of claim 5, wherein the lower portion of the active pattern extends in a first direction substantially parallel to a top surface of the substrate,
and wherein a plurality of the upper portions of the active pattern has an island shape.

7. The semiconductor device of claim 6, wherein the gate electrode extends in a second direction substantially perpendicular to the first direction and substantially parallel to the top surface of the substrate, and surrounds the gate insulation layer pattern.

8. The semiconductor device of claim 5, further comprising a bit line between the insulation layer structure and the vertical channel transistors, the bit line being electrically connected to the first impurity region.

9. The semiconductor device of claim 8, wherein each of the lower portion of the active pattern and the bit line extends in a first direction substantially parallel to a top surface of the substrate.

10. The semiconductor device of claim 1, wherein the insulation layer structure includes a first insulation layer and a second insulation layer sequentially stacked on the substrate.

11. A method of manufacturing a semiconductor device, comprising:
forming a plurality of horizontal channel transistors on a first substrate;
forming a first insulation layer on the first substrate to cover the horizontal channel transistors;
attaching a second substrate on the first insulation layer; and
forming a plurality of vertical channel transistors on the second substrate.

12. The method of claim 11, prior to the forming of the horizontal channel transistors, further comprising forming a plurality of well regions in the first substrate.

13. The method of claim 12, wherein the forming of the well regions includes:
doping n-type impurities in the first substrate to form a first well region; and
doping p-type impurities and n-type impurities on the first well region in the first substrate to form a second well region and a third well region, respectively,
and wherein the forming of the horizontal channel transistors includes forming negative channel metal oxide semiconductor (NMOS) and positive channel metal oxide semiconductor (PMOS) transistors on the second and third well regions, respectively.

14. The method of claim 11, prior to the attaching of the second substrate on the first insulation layer, further comprising forming a conductive layer on the second substrate.

15. The method of claim 14, further comprising forming a second insulation layer on the conductive layer,
and wherein the attaching of the second substrate on the first insulation layer includes attaching the second insulation layer on the first insulation layer.

16. A semiconductor device comprising:
a substrate on which a plurality of first transistors and a plurality of second transistors are formed thereon, wherein each of the first transistors are formed in a peripheral circuit region of the substrate and include a first impurity region, wherein each of the second transistors are formed in the peripheral circuit region and include a second impurity region, wherein each of the first transistors has a horizontal channel disposed between the first impurity regions in a direction substantially parallel to a top surface of the substrate and wherein each of the second transistors has a horizontal channel disposed between the second impurity regions in a direction substantially parallel to the top surface of the substrate;
a first well region, a second well region and a third well region, wherein the second and third well regions are formed under the first and second transistors, respectively and the first well region is formed beneath the second and third well regions;
an insulation layer structure formed on the substrate, the insulation layer structure covering the first and second transistors;
a plurality of third transistors formed on the insulation layer structure in the cell region, wherein the third transistors each include an active pattern having a third impurity region and a fourth impurity region, wherein an upper portion of the active pattern protrudes from a lower portion of the active pattern in a direction substantially perpendicular to the top surface of the substrate, and wherein each of the third transistors includes a channel between the third and fourth impurity regions, respectively;
a buried wiring formed between the insulation layer structure and the third transistors;
a first insulating interlayer formed on the insulation layer structure to cover the lower portion of the active pattern, the buried wiring and the insulation layer structure in the cell region;
a second insulating interlayer formed on the first insulating interlayer to cover the third transistors;
a first plug formed in the second insulating layer in the cell region and electrically connected to the fourth impurity region; and
a second plug formed in the insulation layer structure and the first insulating interlayer in the peripheral circuit region and electrically connected to the first and second impurity regions.

17. The semiconductor device of claim 16, wherein a height of the first insulating interlayer is higher in the peripheral circuit region than a height of the first insulating interlayer in the cell region, wherein the buried wiring contacts with the lower portion of the active pattern and the buried wiring includes tungsten, titanium, tantalum, molybdenum, iridium, hafnium, zirconium, ruthenium, platinum, nickel, aluminum, copper, tungsten nitride, aluminum nitride, tantalum nitride, titanium nitride, titanium aluminum nitride, molybdenum nitride, hafnium nitride, zirconium nitride, doped polysilicon.

18. The semiconductor device of claim 16, wherein the first transistors are each formed in a negative-channel metal oxide semiconductor (NMOS) region of the peripheral circuit region and each further include a first gate structure, wherein the first impurity region is formed at an upper portion of the substrate adjacent to the first gate structure, wherein the second transistors are each formed in a positive-channel metal oxide semiconductor (PMOS) region of the peripheral circuit region and each further include a second gate structure, and wherein the second impurity region is formed at an upper portion of the substrate adjacent to the second gate structure.

19. The semiconductor device of claim 18, wherein the third transistors each further include a gate insulation layer pattern and a gate electrode, wherein the gate insulation layer pattern covers a sidewall of the active pattern and the gate electrode is formed on the gate insulation layer; wherein the third impurity region is formed at a sidewall of the lower portion of the active pattern and the fourth impurity region is formed at an upper surface of the upper portion of the active pattern, and wherein a width of the upper portion of the active patterns of the third transistors is smaller than a width of the lower portion of the active patterns of the third transistors.

20. The semiconductor device of claim 16, further including a capacitor, wherein the capacitor includes a lower electrode formed on the first plug;
a dielectric layer pattern and upper electrode sequentially stacked on the lower electrode, and wherein the capacitor is electrically connected to the fourth impurity region of the active pattern via the first plug.
